(19) United States
(12) Patent Application Publication
(10) Pub. No.: US 2025/0329538 A1
(43) Pub. Date: Oct. 23, 2025

(54) SELECTIVE PLASMA ASSISTED DEPOSITION OF A MOLYBDENUM SILICIDE

(71) Applicant: Applied Materials, Inc., Santa Clara, CA (US)

(72) Inventors: Ying-Bing JIANG, Woodland, CA (US); Joung Joo LEE, San Jose, CA (US); Avgerinos V. GELATOS, Scotts Valley, CA (US); Jiajie CEN, Santa Clara, CA (US); Liqi WU, San Jose, CA (US); Yang HU, Santa Clara, CA (US); Thomas EMPANTE, Santa Clara, CA (US)

(21) Appl. No.: 18/643,137

(22) Filed: Apr. 23, 2024

(51) Int. Cl. H01L 21/285; C23C 16/44; C23C 16/455; C23C 16/52; H01L 21/02

(52) U.S. Cl. CPC H01L 21/28562; C23C 16/4408; C23C 16/45542; C23C 16/52; H01L 21/02697

(57) ABSTRACT

A method includes positioning a substrate within a processing chamber that comprises a feature formed within a dielectric layer formed over an underlayer, delivering an RF power to the processing chamber to generate a plasma over the substrate including: delivering a processing gas during a first time period, delivering a reactive gas into a flow of the processing gas during a second time period to form a pretreatment gas, delivering a deposition gas during a third time period, the deposition gas comprising a precursor gas and the pretreatment gas; and delivering a post-treatment gas during a fourth time period comprising halting the delivering of the precursor gas during the fourth time period, halting the delivering of the RF power and delivering the precursor gas into a flow of the post-treatment gas during a fifth time period, and purging the processing chamber during a sixth time period.

### BACKGROUND

### Field

Embodiments of the invention generally relate to a deposition process for manufacturing semiconductor devices, more particularly, embodiments relate to selectively depositing a metal silicide layer on exposed portions of dielectric structures.

### Description of the Related Art

Integrated circuits have evolved into complex devices that can include millions of transistors, capacitors, and resistors on a single chip. In the course of integrated circuit evolution, functional density (i.e., the number of interconnected devices per chip area) has generally increased while geometry size (i.e., the smallest component (or line) that can be created using a fabrication process) has decreased.

Microelectronic devices are fabricated on a semiconductor substrate as integrated circuits in which various conductive layers are interconnected with one another to permit electronic signals to propagate within the device. Examples of such devices include memory (e.g., DRAM (dynamic random access memory)) and logic devices, including both planar and three-dimensional structures. Three-dimensional structures include fin field-effect transistor (finFET) or metal-oxide-semiconductor field-effect transistor (MOSFET) devices.

An example of finFET or MOSFET devices includes a gate electrode on a gate dielectric layer on a surface of a semiconductor substrate. Source/drain regions are provided along opposite sides of the gate electrode. The source and drain regions are generally heavily doped regions of the semiconductor substrate. Usually a metal silicide layer, for example a titanium silicide layer, is required to form a reliable contact at the formed source and drain regions.

In a traditional middle-end-of-the-line (MEOL) contact junction formation process, a feature, also referred to as a cavity, a via, or a trench, is fabricated in the semiconductor substrate. MEOL contact junctions allow connections between front-end-of-the-line (FEOL) semiconductor structures and back-end-of-the-line (BEOL) interconnects. Contacts with a low resistivity are desirable in semiconductor devices. However, when MEOL contacts have high resistance, the contacts produce poor connections between the FEOL structures and the BEOL packaging interconnects, reducing the performance of the packaged semiconductor structures.

During traditional MEOL contact formation a plasma enhanced process is used to form a metal silicide layer on an exposed portion of a substrate of the cavity, via, or trench. However, during the plasma enhanced process, the metal silicide layer is also deposited of the sidewalls and the field region of the cavity, trench, or via. Therefore, the plasma enhanced process has poor selectivity to the exposed portion of the substrate within the cavity, trench, or via, and has a poor density, homogeneity, thickness, a level of impurities, and the like.

Therefore, there is a need in the art for a metal silicide layer deposition process that is selective to the exposed portion of the substrate within the cavity, trench, or via.

### SUMMARY

According to one or more embodiments, a method for forming a metal silicide layer on a substrate includes positioning a substrate within a processing chamber, the substrate comprising a feature formed within a dielectric layer formed over an underlayer of the substrate; delivering an RF power to the processing chamber to generate a plasma over the substrate, wherein generating the plasma includes: delivering a processing gas during a first time period, delivering a reactive gas into a flow of the processing gas during a second time period to form a pretreatment gas, delivering a deposition gas during a third time period, the deposition gas comprising a precursor gas and the pretreatment gas; and delivering a post-treatment gas during a fourth time period, wherein delivering the post-treatment gas comprises halting the delivering of the precursor gas during the fourth time period to form the post-treatment gas, halting the delivering of the RF power and delivering the precursor gas into a flow of the post-treatment gas during a fifth time period; and purging the processing chamber during a sixth time period.

According to one or more embodiments, a processing system includes a processing chamber, a controller, and a memory storing instructions, which, when executed by the controller, causes the controller to perform a method for forming a metal silicide layer on a substrate, the method including positioning a substrate within the processing chamber, the substrate comprising a feature formed within a dielectric layer formed over an underlayer on the substrate, delivering an RF power to the processing chamber to generate a plasma over the substrate, wherein generating the plasma includes delivering a processing gas during a first time period, delivering a reactive gas into a flow of the processing gas during a second time period to form a pretreatment gas, delivering a deposition gas during a third time period, the deposition gas comprising a precursor gas and the pretreatment gas, and delivering a post-treatment gas during a fourth time period, wherein delivering the post-treatment gas comprises halting the delivering of the precursor gas during the fourth time period to form the post-treatment gas, halting the delivering of the RF power and delivering the precursor gas into a flow of the post-treatment gas during a fifth time period, and purging the processing chamber during a sixth time period.

According to one or more embodiments, a method for forming a metal silicide layer on a substrate includes positioning a substrate within a processing chamber, the substrate comprising a feature formed within a dielectric layer formed over an underlayer on the substrate, delivering an RF power to the processing chamber to generate a plasma over the substrate, wherein generating the plasma includes delivering a processing gas during a first time period, delivering hydrogen (H2) into a flow of the processing gas during a second time period to form a pretreatment gas, delivering a deposition gas during a third time period, the deposition gas comprising a molybdenum (Mo) containing precursor gas and the pretreatment gas, and delivering a post-treatment gas during a fourth time period, wherein delivering the post-treatment gas comprises halting the delivering of the Mo containing precursor gas during the fourth time period to form the post-treatment gas, and halting the delivering of the RF power and delivering the Mo containing precursor gas into a flow of the post-treatment gas during a fifth time period, and purging the processing chamber during a sixth time period.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the disclosure and are therefore not to be considered limiting of its scope, as the disclosure may admit to other equally effective embodiments.

FIG. 1 illustrates a flow chart illustrating a method for fabricating a contact structure according to an embodiment.

FIGS. 2A-2C illustrate schematic cross-sectional views of a contact structure formed on a substrate during various stages of a fabrication process which relate to the operations found in the method illustrated in FIG. 1.

FIG. 3 illustrates a flow chart of a method of forming a metal silicide layer within a contact structure formed on the substrate according to one or more embodiments.

FIG. 4 illustrates a timing diagram illustrating one cycle of the process of forming a metal silicide layer within the contact structure described in FIG. 3 according to one or more embodiments.

FIG. 5 is a schematic cross-sectional view of an example processing system, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

During traditional back-end-of-the-line (BEOL) and middle-end-of-the-line (MEOL) contact formation processes, a plasma enhanced process is used to form a metal silicide layer on an exposed portion of a substrate within a feature, such as a cavity, via, or trench. During the plasma enhanced process, the metal silicide layer is also deposited on the sidewalls and the field region of the feature. Embodiments herein relate to a metal silicide deposition process that is selective to the exposed portion of the substrate.

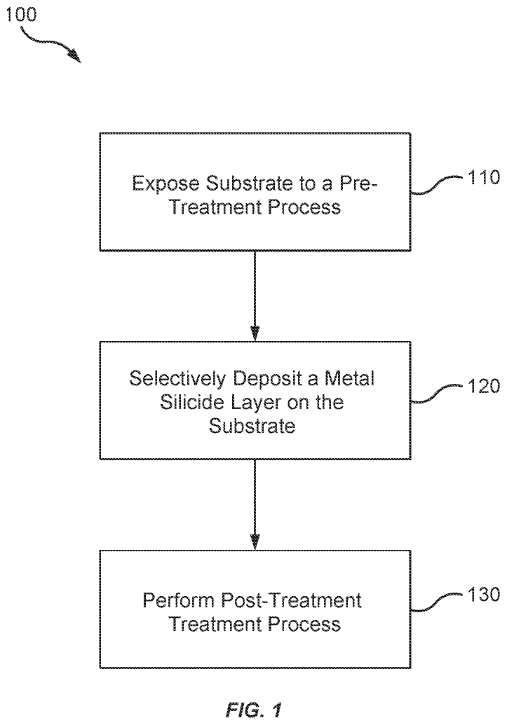

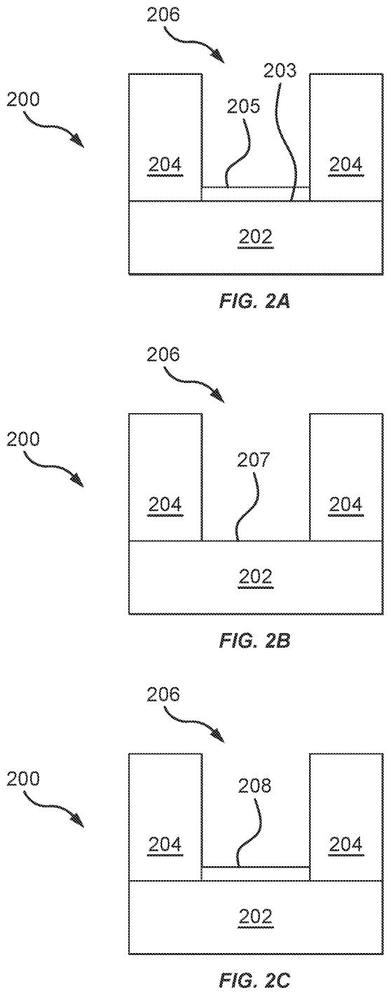

FIG. 1 illustrates a flow chart illustrating a method 100 for fabricating a contact structure according to an embodiment of the invention. The method 100 may be used to selectively deposit a metal silicide layer on a contact surface formed on a substrate. In one embodiment, operations 110-130 of the method 100 may be used on substrate 200 (FIG. 2). The method 100 includes exposing a substrate to pre-treatment process (operation 110), depositing a metal silicide layer on a contact surface formed on a substrate (operation 120), and exposing the substrate to post-treatment process (operation 130). FIGS. 2A-2C illustrate schematic cross-sectional views of a contact structure formed on a substrate 200 during various stages of a fabrication process which relate to the operations found in the method 100 illustrated in FIG. 1.

FIG. 2A depicts substrate 200 having a dielectric layer 204 disposed over an underlayer 202 after being exposed to a polishing process. The underlayer 202 may comprise silicon (Si), silicon germanium (SiGe), germanium (Ge), or the like. A feature 206 (e.g., via, cavity or trench) is formed in the dielectric layer 204 for forming a contact, such as a metal silicide contact. The dielectric layer 204 includes a dielectric material, such as a low-k dielectric material. In one example, dielectric layer 204 contains a low-k dielectric material, such as a silicon carbide oxide material or a carbon doped silicon oxide material, for example, BLACK DIAMOND® II low-k dielectric material, available from Applied Materials, Inc., located in Santa Clara, California.

At operation 110 of the method 100, contaminants 205 may be removed from a portion 203 of the underlayer 202 using a pre-treatment process forming an exposed surface 207 (FIG. 2B) of the underlayer 202 within the feature 206. The exposed surface 207 within the feature 206 is exposed once contaminants 205 are treated or removed from the portion 203 of the underlayer 202 located within the feature 206 (i.e., the contact structure), as illustrated in FIG. 2B. The pre-treatment process exposes the substrate 200 to a reducing agent during a thermal process or a plasma process. The reducing agent may have a liquid state, a gas state, a plasma state, or combinations thereof. Reducing agents that are useful during the pre-treatment process include hydrogen (e.g., H₂ or atomic-H), ammonia (NH₃), a hydrogen and ammonia mixture (H₂/NH₃), atomic-N, hydrazine (N₂H₄), alcohols (e.g., methanol, ethanol, or propanol), derivatives thereof, plasmas thereof, or combinations thereof. The substrate 200 may be exposed to a plasma formed in situ or remotely during the pre-treatment process.

In some embodiments of operation 110, the substrate 200 may be positioned within a processing chamber, exposed to a reducing agent, and heated to a temperature within a range from about 100° C. to about 400° C., such as about 300° C. or about 400° C. The processing chamber may produce an in situ plasma or be equipped with a remote plasma source (RPS). In one embodiment, substrate 200 may be exposed to the plasma (e.g., in situ or remotely) for a time period within a range from about 2 seconds to about 60 seconds. The plasma may be produced at a power within the range from about 50 watts to about 1,000 watts. In one example, substrate 200 may be exposed to hydrogen gas while a plasma is generated at 100 watts for about 10 seconds at about 50 Torr.

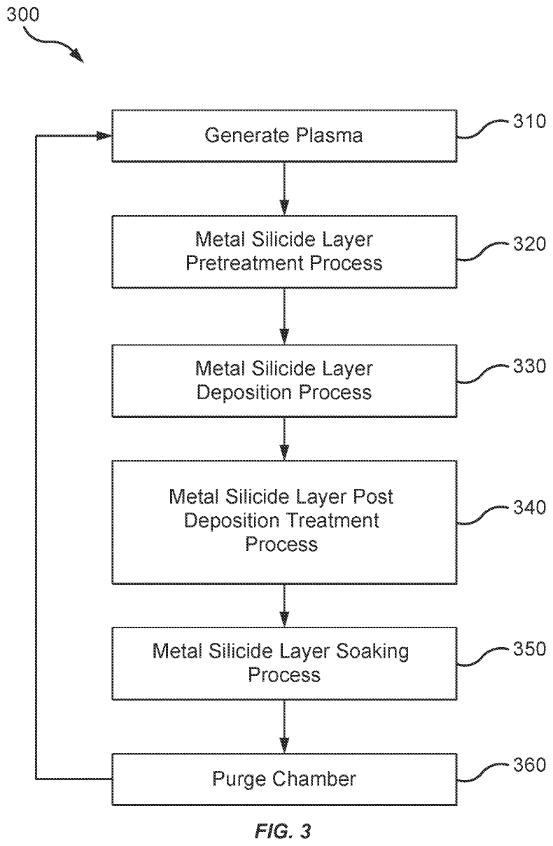

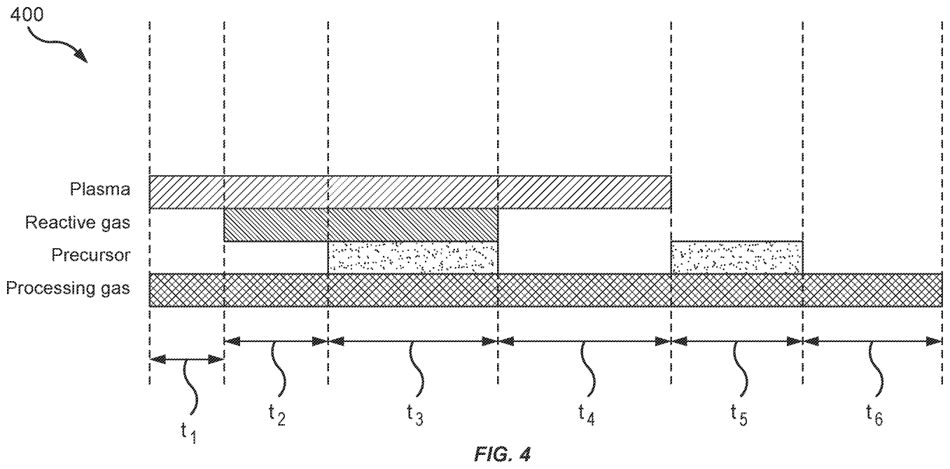

At operation 120 of the method 100, a metal silicide layer 208 is selectively deposited or formed on the exposed surface 207 while leaving the sidewalls of the dielectric layer 204 exposed within the feature 206 and the field region of the dielectric layer 204 bare, as illustrated in FIG. 2C. Therefore, the metal silicide layer 208 is selectively deposited on the exposed surface 207 by use of a metal silicide layer deposition process (method 300). Embodiments of the metal silicide layer deposition process (method 300) are further described in relation to FIG. 3 and FIG. 4.

FIG. 2C illustrates the metal silicide layer formed within the feature 206 after the methods described herein have been performed.

In some embodiments, as discussed further below, operation 120 is repeated at least once, twice, or more. Operation 120 may be performed one time to form a single metal silicide layer 208, or performed multiple times to form metal silicide layers 208, such as 2, 3, 4, 5, or more metal silicide layers 208. In another embodiment, operations 120 and 130 are sequentially repeated at least once, if not, 2, 3, 4 or more times. The metal silicide layer 208 may be deposited having a thickness within a range from about 5 Å to about 70 Å, preferably, from about 10 Å to about 50 Å.

### Metal Silicide Layer Processing Sequence

FIG. 3 illustrates a process flow diagram of a method 300 of forming a metal silicide layer 208 within a contact structure (i.e., the feature 206) formed on the substrate 200 according to one or more embodiments. In some embodiments, the method 300 is performed during the operation 120 of the method 100. In some cases the contact structure is a MEOL or a BEOL structure, according to one or more embodiments of the present disclosure. The method 300 can be used to form a metal silicide layer 208 on an exposed surface 207 of the substrate within the feature 206 (i.e., a contact structure). FIG. 4 illustrates a timing diagram 400 illustrating one cycle of the process of forming a metal silicide layer 208 within the feature 206 described in FIG. 3.

FIGS. 2B-2C are schematic views of a portion of the semiconductor structure including the feature 206, corresponding to various states of the method 300. It should be understood that FIGS. 2B-2C illustrate only a partial schematic view of the semiconductor structure, which may contain any number of transistor sections and additional materials having aspects as illustrated in the figures. It should also be noted that although the method illustrated in FIG. 3 is described sequentially, other sequences that include one or more operations that have been omitted and/or added, and/or has been rearranged in another desirable order, fall within the scope of the embodiments of the disclosure provided herein.

The method 300 begins with operation 310, in which an exposed surface 207 within the feature 206 (i.e., a contact structure) formed in the substrate 200 has already been processed (i.e., cleaned) by use of the processes performed during operation 110, as illustrated in FIG. 2B. During operation 310, at the start of method 300 of operation 120, a plasma is generated over a surface of the substrate 200 that has been positioned in a plasma processing chamber.

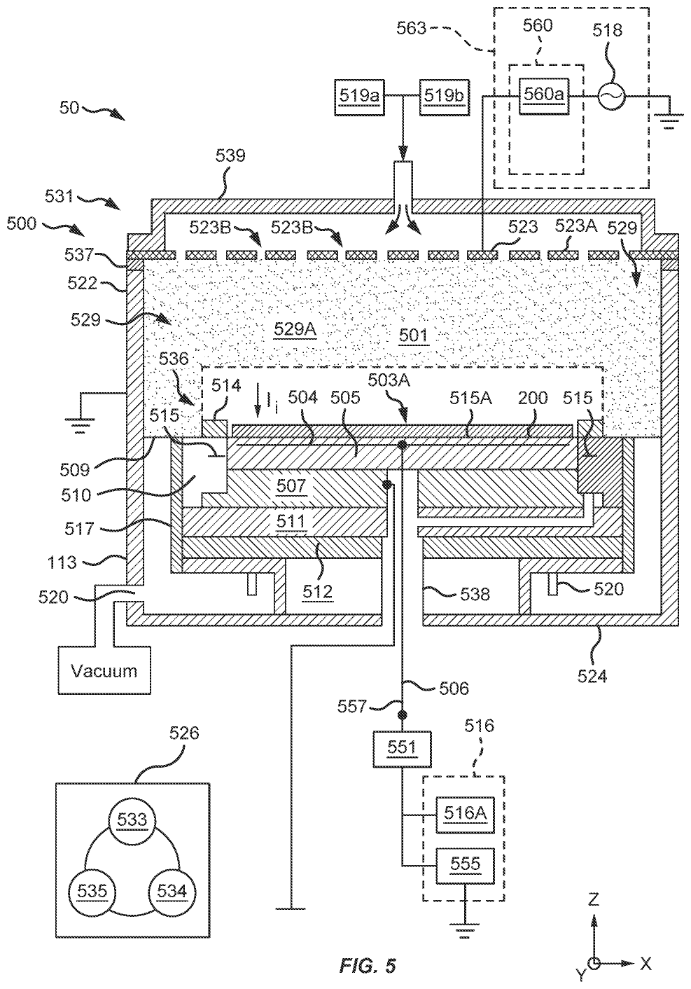

In some embodiments, the plasma processing chamber (e.g., as shown in FIG. 5) includes a capacitively coupled plasma (CCP) plasma processing chamber that includes a showerhead that is configured to provide one or more process gases to a processing region of the plasma processing chamber. In some embodiments, the showerhead is electrically coupled to an RF source to form a plasma in the processing region of the plasma processing chamber as described in more detail below.

As shown in FIG. 4, in some embodiments, the plasma is generated by providing a processing gas, such as argon (Ar), to the processing region of the plasma processing chamber and RF biasing the showerhead at first RF power. The processing gas is provided at a processing gas flow rate between 200 and 10000 sccm at a pressure less than or equal to 50 Torr. The generated plasma may be formed to assure ignition of the plasma and expose the surface of the substrate to the formed plasma. In one or more examples, the plasma is generated (i.e., operation 310) during a first time period t1. In one or more examples, the duration of the first time period is between 0.5 and 10 seconds such as about 2 seconds. Stated differently, operation 310 may be maintained during a time period between 0.5 and 10 seconds, such as about 2 seconds.

The plasma may be generated during one or more of the operations performed during the performance of method 300 by use of a remote plasma source (RPS) system, or the plasma may be generated in situ a plasma capable deposition chamber, such as a PE-CVD chamber (e.g., as shown in FIG. 5) during a plasma treatment process, such as the plasma based operations described in relation to FIGS. 1 and 3. The plasma may be generated from a microwave (MW) frequency generator or a radio frequency (RF) generator. In one example, an in-situ plasma is a capacitively coupled plasma generated by the delivery of RF power from an RF generator. In one or more examples, the delivery of the RF power from the RF generator is less than or equal to 1000 W during the method 300. For example, the RF power delivered is between 50-1000 W.

Next, at operation 320, a metal silicide layer pretreatment process is performed on the exposed surface 207 of the substrate 200. The metal silicide layer pretreatment process can include delivering a reactive gas, such as hydrogen (H₂), into the flow of the processing gas to form a pretreatment gas (e.g., Ar+H₂) that is provided to the plasma formed over the surface of the substrate 200. As shown in FIG. 4, the metal silicide layer pre-treatment process (operation 320) may be performed over a second time period t2. The metal silicide layer pretreatment process includes adding the reactive gas at the conclusion of the first time period t1 to the processing chamber while the processing gas is still being provided to the processing chamber. The metal silicide layer pre-treatment process (i.e., the second time period t2) may be performed in the processing region of the plasma processing chamber for a time period between 0.5 and 10 seconds, such as about 2 seconds, while a second RF power is applied to the showerhead to adjust, control and maintain the formed plasma. The second RF power may be between 50-200 W, such as 50-150 W. In one or more examples, the reactive gas is flowed into the processing chamber at a first reactive gas flow rate between 1 and 10000 sccm. The processing gas is provided at the processing gas flow rate. In one example, a ratio between the first reactive gas flow rate and the processing gas flow rate ranges from 1:200 and 5:1 during the second time period t2. Stated otherwise, in one or more examples, the addition of the reactive gas during operation 320 is optional.

Next, at operation 330, a metal silicide layer deposition process is performed. The metal silicide layer deposition process includes a plasma deposition process in which a precursor gas, such as a molybdenum (Mo) containing precursor gas, is added to the flow of the pretreatment gas to form a deposition gas. The deposition gas is used to cause a metal silicide layer 208, such as a molybdenum silicide (MoSiₓ) layer, to be selectively formed on the exposed surface 207 of the feature 206. In some embodiments, the molybdenum containing precursor gas can include molybdenum pentachloride (MoCl₅). The precursor gas is provided at a first precursor gas flow rate between 0.1 and 50 sccm. As shown in FIG. 4, the metal silicide layer deposition process (operation 330) may be performed over a third time period t3. The metal silicide layer deposition process includes adding the precursor gas at the conclusion of the second time period t2 to the processing chamber while the processing gas and the reactive gas are still being provided to the processing chamber. The metal silicide layer deposition process (i.e., the third time period t3) may be performed in the processing region of the plasma processing chamber for a time period between 0.5 and 10 seconds, such as about 3 seconds at a pressure between 2 and 50 Torr. The metal silicide layer deposition process is performed at a third RF power level. The third RF power level may be equal to or different from the first RF power level, and/or the second RF power level. In one example, the third RF power level is between 50 W and 200 W, such as between 50 W and 150 W. The processing gas is provided at the processing gas flow rate and the reactive gas is provided at the first reactive gas flow rate during the third time period t3. Thus, a ratio between the first reactive gas flow rate and the processing gas flow rate ranges from 1:200 and 5:1 during the third time period t3. A ratio between the first reactive gas flow rate gas and the first precursor gas flow rate ranges from 1:50 to 100000:1, during the third time period t3. Stated otherwise, in one or more examples, the addition of the reactive gas during operation 330 is optional.

At operation 340, a metal silicide layer post deposition treatment process is performed on the metal silicide layer 208 of the substrate 200. The metal silicide layer post deposition treatment process can include continuing to deliver the reactive gas, such as hydrogen (H₂), into a flow of the processing gas to form post-treatment gas (e.g., Ar+H₂) that is provided to the formed plasma formed over the surface of the substrate 200. In one embodiment, the post-treatment gas can be formed by only delivering the reactive gas or the processing gas. In another example, the post-treatment gas includes a mixture of the processing gas and the reactive gas. The reactive gas may be provided at a second reactive gas flow rate between 1 and 10000 sccm. The second reactive gas flow rate may be greater than, less than, or equal to the first reactive gas flow rate. As shown in FIG. 4, the metal silicide layer post deposition treatment process (operation 340) may be performed over a fourth time period t4. The metal silicide layer post deposition treatment process includes ceasing to add the precursor gas at the conclusion of the third time period t3 to the processing chamber while the processing gas and the reactive gas are still being provided to the processing chamber, forming the post-treatment gas. The metal silicide layer post deposition treatment process (i.e., the fourth time period t4) may be performed in the processing region of the plasma processing chamber for a time period between 2 and 4 seconds, such as about 3 seconds. The metal silicide layer post deposition treatment process is performed at a fourth RF power level. The fourth RF power level may be equal to or different from the first RF power level, the second RF power level, and/or the third RF power level. The fourth RF power level may be between 50 W and 1000 W. The processing gas is provided at the processing gas rate during the metal silicide layer post deposition treatment process. A ratio between the second reactive gas flow rate and the processing gas flow rate ranges from 1:200 and 5:1 during the fourth time period t4. Stated otherwise, in one or more examples, the addition of the reactive gas during operation 340 is optional.

In one example, operations 310-340 are performed at a same processing chamber pressure. In one embodiment, during operations 310-340 the processing chamber is maintained at a pressure greater than 50 Torr, such as 25 Torr. On the other hand, each or some of the operations 310-340 may be performed at different chamber pressures that are greater than 2 Torr. For example, the chamber pressure of each operation 310-340 may be different. In another example, the chamber pressure of operation 310 may be different than the chamber pressure of operations 320-340, the chamber pressures of operations 310 and 330 may be different than the chamber pressure of operations 320 and 340, and so on.

At operation 350, a metal silicide layer soaking process is performed. The metal silicide layer soaking process is used for quality control and selective tuning of the metal silicide layer 208. For example, the metal silicide layer soaking process removes byproducts or intermediate growth products on the growth surface of the metal silicide layer 208, and conditions the processing chamber environment. The metal silicide layer soaking process may be performed by thermal decomposition of the precursor gas carried by a process gas mixture that includes the reactive gas (H₂) and the processing gas (e.g., Ar). In operation 350, the plasma is no longer being generated (i.e., the plasma is turned off) and the precursor gas and at least the reactive gas may be provided to the processing chamber. Stated differently, the RF power is no longer being delivered to the processing chamber and the precursor gas is added to a flow of the post-treatment gas.

As shown in FIG. 4, the metal silicide layer soaking process (operation 350) may be performed over a fifth time period t5. The metal silicide layer soaking process includes ceasing to form the plasma and adding the precursor gas at the conclusion of the fourth time period t4 to the processing chamber while the processing gas and the reactive gas (i.e., the post-treatment gas) are still being provided to the processing chamber. The reactive gas may be provided to the processing chamber at a third reactive gas flow rate between 1 and 10000 sccm. The third reactive gas flow rate may be equal to or different from the second reactive gas flow rate. The third reactive gas flow rate may be equal to or different from the first reactive gas flow rate. The precursor gas may be provided to the processing chamber at a second precursor gas flow rate between 0.1 and 50 sccm. The second precursor gas flow rate may be the equal to or different from the first gas precursor flow rate. The processing gas is provided at the processing gas flow rate during the fifth time period t5. Thus, a ratio between the third reactive gas flow rate the processing gas flow rate ranges from 1:200 and 5:1 during the fifth time period t5. A ratio between the third reactive gas flow rate gas and the second precursor gas flow rate ranges from 1:50 to 100000:1 during the fifth time period t5. Stated otherwise, in one or more examples, the addition of the reactive gas during operation 350 is optional.

The metal silicide layer soaking process (i.e., the fifth time period t5) may be performed in the processing region of the plasma processing chamber for a time period between 0.5 and 10 seconds, such as about 5 seconds. In one or more examples, operation 350 is performed at a chamber pressure greater than 5 Torr. The chamber pressure used in operation 350 may be greater than, less than, or equal to each of the chamber pressures used in operations 310-340.

Next, at operation 360, a process gas mixture, which can include the reactive gas (H₂) and the processing gas (e.g., Ar), are provided for a desired time period to the processing region of the plasma processing chamber to purge the processing chamber (i.e., perform a purge process). As shown in FIG. 4, the purge process (operation 360) may be performed over a sixth time period t6. The purge process includes ceasing to add the precursor gas at the conclusion of the fifth time period t5 to the processing chamber while the processing gas and the reactive gas are still being provided to the processing chamber. In one embodiment, the processing chamber is purged with a purging gas comprising the reactive gas and the processing gas. In one embodiment, the majority of the chemistry of the purge gas is formed by the reactive gas. For example, a concentration of the relative gas in the purge gas may be 0.1-100%. In some embodiments, the processing chamber may be maintained at a pressure between 1 m Torr and 5000 m Torr. The reactive gas may be provided at a fourth reactive gas flow rate between 1 and 10000 sccm. The fourth reactive gas flow rate may be equal to or different from the third reactive gas flow rate, the second reactive gas flow rate, and/or the first reactive gas flow rate. The processing gas is provided at the processing gas flow rate during the sixth time period t6. Thus, a ratio between the fourth reactive gas flow rate and the processing gas flow rate ranges from 1:200 and 5:1 during the sixth time period t6.

The purge process (i.e., the sixth time period t6) may be performed in the processing region of the plasma processing chamber for a time period between 0.5 and 7 seconds, such as between about 2 and about 6 seconds. In one or more examples, operation 360 is performed at a chamber pressure less than or equal to 50 Torr. The chamber pressure used in operation 360 may be greater than, less than, or equal to each of the chamber pressures used in operations 310-350.

After the purge process (i.e., operation 360), the method 300 returns to operation 310 and repeats operations 310-360 for a quantity of cycles. The method 300 may be repeated for a quantity of cycles until the metal silicide layer 208 reaches a desired thickness. In one or more examples, the desired thickness is between 5 Å and 70 Å, preferably, from about 10 Å to about 50 Å. For example the quantity of cycles may be between 50 and 500 cycles.

In one or more examples, after the metal silicide layer 208 reaches the desired thickness, further processing is performed on the contact structure (i.e., operation 130). Further processing may include, but is not limited to, depositing a metal capping layer over the metal silicide layer, such as a Mo or tungsten (W) metal capping layer, and annealing the substrate 200.

FIG. 5 is a schematic cross-sectional view of an example processing system 50, according to one or more embodiments. In some embodiments, the processing system 50 illustrated in FIG. 5 is configured for plasma-assisted etching processes, such as reactive ion etch (RIE) plasma processing. However, it should be noted that the embodiments described herein may also be used with processing systems configured for used in other plasma-assisted processes, such as plasma-enhanced deposition processes, for example, plasma-enhanced chemical vapor deposition (PECVD) processes, plasma-enhanced physical vapor deposition (PEPVD) processes, plasma-enhanced atomic layer deposition (PEALD) processes, plasma treatment processing or plasma-based ion implant processing, for example, plasma doping (PLAD) processing.

As shown in FIG. 5 the processing system 50 is configured to form a capacitively coupled plasma (CCP), where the processing system 50 includes an upper electrode (e.g., showerhead 523) disposed in a processing volume 529 facing a lower electrode (e.g., the substrate support assembly 536) also disposed in the processing volume 129. A plasma generator assembly 563 is electrically coupled to one of the upper electrode or lower electrode to deliver an RF signal that is used to ignite and maintain a plasma 501 in a processing region 529A disposed over the substrate 200. The plasma generator assembly 563 generally includes an RF generator 518 and an RF matching network 560 coupled to the RF generator 518. In one example, the output of the RF matching network 560 is coupled to the upper electrode. In some embodiments, the RF generator 518 is configured to deliver an RF signal having a frequency that is greater than 400 kHz, such as an RF frequency ranging between 300 KHz and 2.47 GHZ, such as between 350 kHz and 100 MHz.

The processing system 50 further includes a processing chamber 500, the substrate support assembly 536, and a system controller 526. The processing chamber 500 typically includes a chamber body 513 that includes a chamber lid 539, one or more sidewalls 522, and a chamber base 524, which collectively define the processing volume 529. A substrate 200 is loaded into, and removed from, the processing volume 529 through an opening (not shown) in one of the one or more sidewalls 522, which is sealed with a slit valve (not shown) during plasma processing of the substrate 200. The one or more sidewalls 522 and chamber base 524 generally include materials that are sized and shaped to form the structural support for the elements of the processing chamber 500 and are configured to withstand the pressures and added energy applied to them while a plasma 501 is generated within a vacuum environment maintained in the processing volume 529 of the processing chamber 500 during processing. In one example, the one or more sidewalls 522 and chamber base 524 are formed from a metal, such as aluminum, an aluminum alloy, or a stainless steel alloy. In some embodiments, there is a dielectric coating on the sidewalls 522. The dielectric coating can be anodized aluminum, aluminum oxide, yttrium oxide, mixtures thereof. The thickness of the dielectric coating can vary from 100 nm to 10 cm.

The system controller 526, also referred to herein as a processing chamber controller, includes a central processing unit (CPU) 533, a memory 534, and support circuits 535. The system controller 526 is used to control the process sequence used to process the substrate 503, including the substrate biasing methods described herein. The CPU 133 is a general-purpose computer processor configured for use in an industrial setting for controlling the processing chamber and sub-processors related thereto. The memory 534 described herein, which is generally non-volatile memory, may include random access memory, read-only memory, floppy or hard disk drive, or other suitable forms of digital storage, local or remote. The support circuits 535 are conventionally coupled to the CPU 533 and comprise cache, clock circuits, input/output subsystems, power supplies, and the like, and combinations thereof. Software instructions (program) and data can be coded and stored within the memory 534 for instructing a processor within the CPU 533. A software program (or computer instructions) readable by CPU 533 in the system controller 526 determines which tasks are performable by the components in the processing system 50. Typically, the program, which is readable by CPU 533 in the system controller 526, includes code, which, when executed by the processor (CPU 533), performs tasks relating to the plasma processing schemes described herein. The program may include instructions that are used to control the various hardware and electrical components within the processing system 10A to perform the various process tasks and various process sequences used to implement the methods described herein. In one embodiment, the program includes instructions that are used to perform one or more of the operations described above.

The substrate support assembly 536, which generally includes a substrate support 505 (e.g., electrostatic-chuck (ESC) substrate support) and a support base 507, is disposed on a support shaft 538 that is grounded and extends through the chamber base 524. In some embodiments, the substrate support assembly 536 can additionally include an insulator plate 511 and a ground plate 512. The support base 507 is electrically isolated from the chamber base 524 by the insulator plate 511, and the ground plate 512 is interposed between the insulator plate 511 and the chamber base 524. The substrate support 505 is thermally coupled to and disposed on the support base 507. In some embodiments, the support base 507 is configured to regulate the temperature of the substrate support 505, and the substrate 200 disposed on the substrate support 505, during substrate processing. In some embodiments, the support base 507 includes one or more cooling channels (not shown) disposed therein that are fluidly coupled to, and in fluid communication with, a coolant source (not shown), such as a refrigerant source or water source having a relatively high electrical resistance. In some embodiments, the substrate support 505 includes a heater (not shown), such as a resistive heating element embedded in the dielectric material thereof. Herein, the support base 507 is formed of a corrosion-resistant thermally conductive material, such as a corrosion-resistant metal, for example aluminum, an aluminum alloy, or a stainless steel and is coupled to the substrate support with an adhesive or by mechanical means.

In some embodiments, the process chamber 500 further includes a quartz pipe 510, or collar, that at least partially circumscribes portions of the substrate support assembly 536 to prevent the substrate support 505 and/or the support base 507 from contact with corrosive processing gases or plasma, cleaning gases or plasma, or byproducts thereof. Typically, the quartz pipe 510, the insulator plate 511, and the ground plate 512 are circumscribed by a cathode liner 517. In some embodiments, a plasma screen 509 is positioned between the cathode liner 508 and the sidewalls 522 to prevent plasma from forming in a volume underneath the plasma screen 509 between the cathode liner 108 and the one or more sidewalls 522.

The substrate support 505 is typically formed of a dielectric material, such as a bulk sintered ceramic material, such as a corrosion-resistant metal oxide or metal nitride material, for example, aluminum oxide (Al₂O₃), aluminum nitride (AlN), titanium oxide (TiO), titanium nitride (TiN), yttrium oxide (Y₂O₃), mixtures thereof, or combinations thereof. In embodiments herein, the substrate support 505 further includes a bias electrode 504 embedded in the dielectric material thereof. In one configuration, the bias electrode 504 is a chucking pole used to secure (i.e., chuck) the substrate 200 to the substrate support surface 505A of the substrate support 505 and to bias the substrate 200 with respect to the plasma 501 using one or more of the pulsed-voltage biasing schemes described herein. Typically, the bias electrode 504 is formed of one or more electrically conductive parts, such as one or more metal meshes, foils, plates, or combinations thereof.

In some embodiments, the showerhead 523 and substrate support assembly 136 are configured in a parallel plate like configuration, such that the surface 523A of the showerhead 523 is substantially parallel to the substrate support surface 505A of the of the substrate support assembly 536. In some alternate embodiments, the showerhead 523 has a low angled concave conical shape or slightly curved concave shape relative to the flat substrate support assembly 536, which is centered about the center of showerhead 523.

The substrate support assembly 536 has an edge ring 514 positioned within a region of the substrate support 505. For example, the edge ring 514 is disposed on and adjacent to the substrate support 505. In this configuration, the edge ring 514 is formed from a semiconductor or dielectric material (e.g., AlN, etc.).

In some embodiments, the bias electrode 504 is electrically coupled to a clamping network 516, which provides a chucking voltage thereto, such as static DC voltage between about −5000 V and about 10,000 V, using an electrical conductor, such as a coaxial power delivery line 506 (e.g., a coaxial cable). The application of a sufficient clamping voltage to the bias electrode 504 can facilitate the temperature control of the substrate 200 and the edge ring 514. The clamping network 516 includes bias compensation circuit elements 516A, and a DC power supply 555. In some embodiments, the clamping network is coupled to an RF filter assembly 551 that is configured to block the RF signal generated by the plasma generator assembly 563 and any associated harmonics, from making their way to the clamping network 516 or the DC power supply 555.

In some embodiments, an upper electrode assembly 531 includes the upper electrode (e.g., showerhead 523) and a lid plate 539, which are configured to evenly distribute one or more gases provided from a first processing gas source 519a and a second processing gas source 519b to the process region 529A through a plurality of holes 523B formed in the upper electrode. For example, the first processing gas source 519a may provide the process gas and/or the precursor and the second processing gas source 519b may provide the process gas and/or the reactive gas (or vice versa). The processing volume 529 is fluidly coupled to one or more dedicated vacuum pumps through a vacuum outlet 520, which maintain the processing volume 529 at sub-atmospheric pressure conditions and evacuate processing and/or other gases, therefrom.

The upper electrode assembly 531 is also positioned on, and electrically isolated from, the grounded sidewalls 522 by a lid insulator 537. As shown in FIG. 5, one or more components of the substrate support assembly 536, such as the support base 507 are grounded.

While the foregoing is directed to embodiments of the invention, other and further embodiments of the invention may be devised without departing from the basic scope thereof, and the scope thereof is determined by the claims that follow.

What is claimed is:

1. A method for forming a metal silicide layer on a substrate, the method comprising:
positioning a substrate within a processing chamber, the substrate comprising a feature formed within a dielectric layer formed over an underlayer of the substrate;
delivering RF power to the processing chamber to generate a plasma over the substrate, wherein generating the plasma comprises:
delivering a processing gas during a first time period;
delivering a reactive gas into a flow of the processing gas during a second time period to form a pretreatment gas;
delivering a deposition gas during a third time period, the deposition gas comprising a precursor gas and the pretreatment gas; and
delivering a post-treatment gas during a fourth time period, wherein delivering the post-treatment gas comprises halting the delivering of the precursor gas during the fourth time period to form the post-treatment gas;
halting the delivering of the RF power and delivering the precursor gas into a flow of the post-treatment gas during a fifth time period; and
purging the processing chamber during a sixth time period.

2. The method of claim 1, wherein the precursor gas comprises a molybdenum (Mo) containing precursor gas.

3. The method of claim 2, wherein the Mo containing precursor gas comprises molybdenum pentachloride (MoCl₅).

4. The method of claim 1, wherein the reactive gas is delivered at a first reactive gas flow rate during the second time period and the third time period, at a second reactive gas flow rate during the fourth time period, at a third reactive gas flow rate during the fifth time period, and a fourth reactive gas flow rate during the sixth time period.

5. The method of claim 4, wherein the precursor gas is delivered at a first precursor gas flow rate during the third time period, and a ratio between the first reactive gas flow rate and the first precursor gas flow rate is between 1:50 and 100000:1.

6. The method of claim 4, wherein the processing gas is provided at a processing gas flow rate in the first, second, third, fourth, fifth, and sixth time periods.

7. The method of claim 6, wherein a ratio between the first reactive gas flow rate and the processing gas flow rate is between 1:200 and 5:1.

8. The method of claim 6, wherein a ratio between the second reactive gas flow rate and the processing gas flow rate is between 0:1 and 5:1.

9. The method of claim 6, wherein a ratio between the third reactive gas flow rate and the processing gas flow rate is between 1:200 and 5:1.

10. The method of claim 6, wherein a ratio between the fourth reactive gas flow rate and the processing gas flow rate is between 1:200 and 5:1.

11. A processing system comprising:
a processing chamber;
a controller; and
a memory storing instructions, which, when executed by the controller, causes the controller to perform a method for forming a metal silicide layer on a substrate, the method comprising:
positioning a substrate within the processing chamber, the substrate comprising a feature formed within a dielectric layer formed over an underlayer on the substrate;
delivering an RF power to the processing chamber to generate a plasma over the substrate, wherein generating the plasma comprises:
delivering a processing gas during a first time period;
delivering a reactive gas into a flow of the processing gas during a second time period to form a pretreatment gas;
delivering a deposition gas during a third time period, the deposition gas comprising a precursor gas and the pretreatment gas; and
delivering a post-treatment gas during a fourth time period, wherein delivering the post-treatment gas comprises halting the delivering of the precursor gas during the fourth time period to form the post-treatment gas;
halting the delivering of the RF power and delivering the precursor gas into a flow of the post-treatment gas during a fifth time period; and
purging the processing chamber during a sixth time period.

12. The processing system of claim 11, wherein the reactive gas is delivered at a first reactive gas flow rate during the second time period and the third time period, at a second reactive gas flow rate during the fourth time period, at a third reactive gas flow rate during the fifth time period, and a fourth reactive gas flow rate during the sixth time period.

13. The processing system of claim 12, wherein the precursor gas is delivered at a first precursor gas flow rate during the third time period, and a ratio between the first reactive gas flow rate and the first precursor gas flow rate is between 1:50 and 100000:1.

14. The processing system of claim 12, wherein the processing gas is provided at a processing gas flow rate in the first, second, third, fourth, fifth, and sixth time periods.

15. The processing system of claim 14, wherein a ratio between the first reactive gas flow rate and the processing gas flow rate is between 1:200 and 5:1.

16. The processing system of claim 14, wherein a ratio between the second reactive gas flow rate and the processing gas flow rate is between 1:200 and 5:1.

17. The processing system of claim 14, wherein a ratio between the third reactive gas flow rate and the processing gas flow rate is between 1:200 and 5:1.

18. The processing system of claim 14, wherein a ratio between the fourth reactive gas flow rate and the processing gas flow rate is between 1:200 and 5:1.

19. The processing system of claim 11, wherein the precursor gas comprises molybdenum pentachloride (MoCl₅).

20. A method for forming a metal silicide layer on a substrate, the method comprising:
positioning a substrate within a processing chamber, the substrate comprising a feature formed within a dielectric layer formed over an underlayer on the substrate;
delivering an RF power to the processing chamber to generate a plasma over the substrate, wherein generating the plasma comprises:
delivering a processing gas during a first time period;
delivering hydrogen (H₂) into a flow of the processing gas during a second time period to form a pretreatment gas;
delivering a deposition gas during a third time period, the deposition gas comprising a molybdenum (Mo) containing precursor gas and the pretreatment gas; and
delivering a post-treatment gas during a fourth time period, wherein delivering the post-treatment gas comprises halting the delivering of the Mo containing precursor gas during the fourth time period to form the post-treatment gas; and
halting the delivering of the RF power and delivering the Mo containing precursor gas into a flow of the post-treatment gas during a fifth time period; and
purging the processing chamber during a sixth time period.
